(19) United States
(12) Patent Application Publication
(10) Pub. No.: US 2024/0162860 A1
(43) Pub. Date: May 16, 2024

(54) POWER AMPLIFIER CIRCUIT AND POWER AMPLIFICATION METHOD

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/408,591

(22) Filed: Jan. 10, 2024

Related U.S. Application Data
(63) Continuation of application No. PCT/JP2022/023624, filed on Jun. 13, 2022.

(30) Foreign Application Priority Data
Jul. 20, 2021 (JP) 2021-119997

(51) Int. Cl. H03F 1/02; H03F 3/24

(52) U.S. Cl. CPC H03F 1/0233; H03F 3/245; H03F 2200/105; H03F 2200/451

(57) ABSTRACT

A power amplifier circuit includes an external input terminal, an external output terminal, a power amplifier connected to the external input terminal, power amplifiers, a power supply terminal connected to the power amplifier, and a power supply terminal connected to the power amplifier. The power amplifiers are connected in parallel with each other between the power amplifier and the external output terminal. A first power supply voltage which is variable to multiple discrete first voltage levels is supplied to the power amplifier via the power supply terminal. A second power supply voltage which is variable to multiple discrete second voltage levels is supplied to the power amplifier via the power supply terminal. The multiple discrete second voltage levels are different from the multiple discrete first voltage levels.

### CROSS-REFERENCE TO RELATED APPLICATIONS

This is a continuation application of PCT/JP2022/023624, filed on Jun. 13, 2022, designating the United States of America, which is based on and claims priority to Japanese Patent Application No. JP 2021-119997 filed on Jul. 20, 2021. The entire contents of the above-identified applications, including the specifications, drawings and claims, are incorporated herein by reference in their entirety.

### TECHNICAL FIELD

The present disclosure relates to a power amplifier circuit and a power amplification method.

### BACKGROUND ART

These days, power amplification efficiency is improving by the application of an envelope tracking (ET) mode to a power amplifier circuit. Additionally, a technology for supplying a power supply voltage of multiple discrete voltage levels in the ET mode is disclosed (see Patent Document 1, for example).

### CITATION LIST

### Patent Document

Patent Document 1: U.S. Pat. No. 8,829,993

### Summary of Disclosure

### Technical Problem

However, the supplying of a power supply voltage of multiple discrete voltage levels to a multistage amplifier circuit, as disclosed in Patent Document 1, may decrease the efficiency.

It is an object of the present disclosure to provide a power amplifier circuit and a power amplification method that can regulate a decrease in efficiency, which is caused by using multiple discrete voltage levels for a power supply voltage.

### Solution to Problem

A power amplifier circuit according to an aspect of the disclosure includes an external input terminal, an external output terminal, a first power amplifier connected to the external input terminal, second and third power amplifiers, a first power supply terminal connected to the second power amplifier, and a second power supply terminal connected to the third power amplifier. The second and third power amplifiers are connected in parallel with each other between the first power amplifier and the external output terminal. A first power supply voltage which is variable to multiple discrete first voltage levels is supplied to the second power amplifier via the first power supply terminal. A second power supply voltage which is variable to multiple discrete second voltage levels is supplied to the third power amplifier via the second power supply terminal. The multiple discrete second voltage levels are different from the multiple discrete first voltage levels.

A power amplifier circuit according to an aspect of the disclosure includes an external input terminal, an external output terminal, a first power amplifier connected to the external input terminal, second and third power amplifiers, and first and second power supply terminals separately connected to different terminals of a digital tracker. The second and third power amplifiers are connected in parallel with each other between the first power amplifier and the external output terminal. The first power supply terminal is connected to the second power amplifier. The second power supply terminal is connected to the third power amplifier.

A power amplification method according to an aspect of the disclosure is a power amplification method for amplifying power of a radio-frequency signal by using second and third power amplifiers. The second and third power amplifiers are connected in parallel with each other between a first power amplifier and an external output terminal. The first power amplifier is connected to an external input terminal. The power amplification method includes: supplying a first power supply voltage which is variable to multiple discrete first voltage levels to the second power amplifier; and supplying a second power supply voltage which is variable to multiple discrete second voltage levels to the third power amplifier. The multiple discrete second voltage levels are different from the multiple discrete first voltage levels.

### Effects of Disclosure

Using a power amplifier circuit according to an aspect of the disclosure can regulate a decrease in efficiency, which is caused by using multiple discrete voltage levels for a power supply voltage.

### BRIEF DESCRIPTION OF DRAWINGS

FIG. 1 is a circuit diagram of a power amplifier circuit, a radio-frequency circuit, and a communication device according to a first embodiment.

FIG. 2 is a circuit diagram of a power supply circuit according to the first embodiment.

FIG. 3A is a graph illustrating an example of the transition of a power supply voltage in an analog ET mode.

FIG. 3B is a graph illustrating an example of the transition of a power supply voltage in a digital ET mode.

FIG. 3C is a graph illustrating an example of the transition of a power supply voltage in an APT (Average Power Tracking) mode.

FIG. 4 is a sequence diagram illustrating an operation of the communication device according to the first embodiment.

FIG. 5A is a graph illustrating an example of the efficiency of a carrier amplifier to which the APT mode is applied in the first embodiment.

FIG. 5B is a graph illustrating an example of the efficiency of a peaking amplifier to which the digital ET mode is applied in the first embodiment.

FIG. 5C is a graph illustrating an example of the efficiency of the carrier amplifier to which the APT mode is applied and the peaking amplifier to which the digital ET mode is applied in the first embodiment.

FIG. 5D is a graph illustrating an example of the efficiency of a carrier amplifier to which the APT mode is applied and a peaking amplifier to which a voltage fixed mode is applied in a comparative example.

FIG. 6 is a circuit diagram of a power supply circuit according to a modified example of the first embodiment.

FIG. 7 is a graph illustrating an example of the efficiency of a carrier amplifier to which the digital ET mode is applied in the modified example of the first embodiment.

FIG. 8 is a circuit diagram of a power amplifier circuit, a radio-frequency circuit, and a communication device according to a second embodiment.

FIG. 9 is a circuit diagram of a power supply circuit according to the second embodiment.

FIG. 10 is a graph illustrating an example of the transition of a power supply voltage in each of first and second digital ET modes in the second embodiment.

FIG. 11A is a graph illustrating an example of the efficiency of a carrier amplifier to which the first digital ET mode is applied and a peaking amplifier to which the second digital ET mode is applied in the second embodiment.

FIG. 11B is a graph illustrating an example of the efficiency of a carrier amplifier and a peaking amplifier to which the first digital ET mode is applied in a comparative example.

FIG. 12 is a graph illustrating an example of the transition of a power supply voltage in each of the first and second digital ET modes in a first modified example of the second embodiment.

FIG. 13 is a graph illustrating an example of the efficiency of a carrier amplifier to which the first digital ET mode is applied and a peaking amplifier to which the second digital ET mode is applied in the first modified example of the second embodiment.

FIG. 14 is a graph illustrating an example of the transition of a power supply voltage in each of the first and second digital ET modes in a second modified example of the second embodiment.

FIG. 15 is a graph illustrating an example of the efficiency of a carrier amplifier to which the first digital ET mode is applied and a peaking amplifier to which the second digital ET mode is applied in the second modified example of the second embodiment.

FIG. 16 is a circuit diagram of a power amplifier circuit, a radio-frequency circuit, and a communication device according to a third embodiment.

FIG. 17 is a circuit diagram of a power supply circuit according to the third embodiment.

### DESCRIPTION OF EMBODIMENTS

Embodiments of the disclosure will be described below in detail with reference to the drawings. All the embodiments described below illustrate general or specific examples. Numerical values, configurations, materials, elements, and positions and connection states of the elements, for example, illustrated in the following embodiments are only examples and are not intended to limit the disclosure.

The drawings are only schematically shown and are not necessarily precisely illustrated. For the sake of representation of the disclosure, some drawings may be illustrated in an exaggerated manner or with omissions or the ratios of elements in the drawings are adjusted. The shapes, positional relationships, and ratios of elements in the drawings may be different from those of the actual elements. In the drawings, substantially identical elements are designated by like reference numeral and an explanation of such elements may be omitted or be merely simplified from the second time.

In the individual drawings, the x axis and the y axis are axes which are perpendicular to each other on a plane parallel with the main surfaces of a module laminate. More specifically, based on the module laminate having a rectangular shape in a plan view, the x axis is parallel with a first side of the module laminate, while the y axis is parallel with a second side, which is perpendicular to the first side of the module laminate. The z axis is an axis perpendicular to the main surfaces of the module laminate. The positive-side direction of the z axis is the upward direction, while the negative-side direction of the z axis is the downward direction.

In the circuit configurations of the disclosure, “A is connected to B” includes, not only the meaning that A is directly connected to B using a connection terminal and/or a wiring conductor, but also the meaning that A is electrically connected to B via another circuit element. “An element is connected between A and B” may be understood as the element is connected to both A and B between A and B and includes the meaning that the element is connected in series with a path connecting A and B and also that the element is parallel-connected (shunt-connected) between this path and a ground. “A and B are connected in parallel with each other between C and D” means that A is connected in series with a path connecting C and D and that B is connected in series with another path connecting C and D. That is, A is connected to C and D without having B interposed therebetween, while B is connected to C and D without having A interposed therebetween. A and/or B may be connected to C and/or D via another circuit element.

### First Embodiment

### [1.1.1 Circuit Configuration]

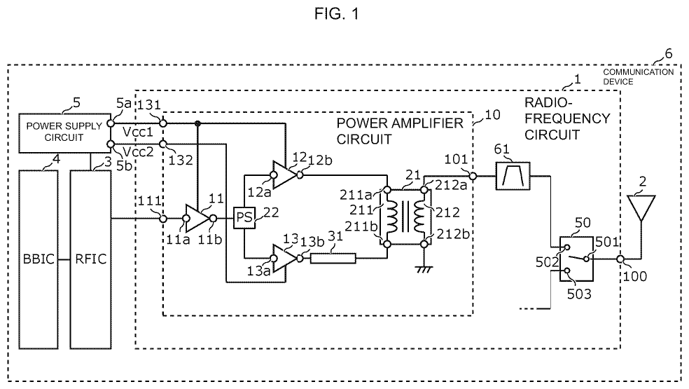

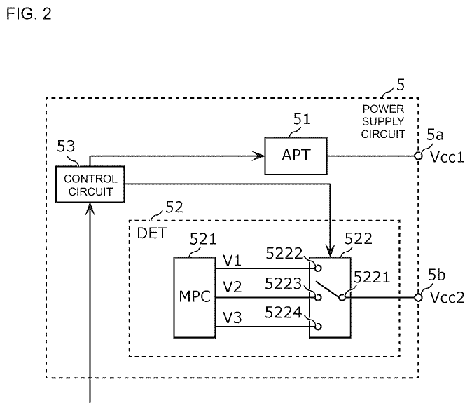

The circuit configurations of a communication device 6, a radio-frequency circuit 1, a power amplifier circuit 10, and a power supply circuit 5 according to the first embodiment will be sequentially described below with reference to FIGS. 1 and 2. FIG. 1 is a circuit diagram of the power amplifier circuit 10, radio-frequency circuit 1, and communication device 6 according to the first embodiment. FIG. 2 is a circuit diagram of the power supply circuit 5 according to the first embodiment. In FIG. 2, a path for receiving power from an external power supply is not shown.

### [1.1.1.1 Circuit Configuration of Communication Device 6]

The circuit configuration of the communication device 6 will first be described below. As illustrated in FIG. 1, the communication device 6 according to the first embodiment includes the radio-frequency circuit 1, an antenna 2, an RFIC (Radio Frequency Integrated Circuit) 3, a BBIC (Baseband Integrated Circuit) 4, and the power supply circuit 5.

The radio-frequency circuit 1 transfers a radio-frequency signal between the antenna 2 and the RFIC 3. The internal configuration of the radio-frequency circuit 1 will be discussed later.

The antenna 2 is connected to an antenna connection terminal 100 of the radio-frequency circuit 1 and transmits a radio-frequency signal output from the radio-frequency circuit 1.

The RFIC 3 is an example of a signal processing circuit that processes a radio-frequency signal. The RFIC 3 will be explained below more specifically. The RFIC 3 performs signal processing, such as up-conversion, on a transmission signal input from the BBIC 4 and outputs the resulting radio-frequency transmission signal to a transmit path of the radio-frequency circuit 1. The RFIC 3 includes a controller that controls the radio-frequency circuit 1 and the power supply circuit 5. All or some of the functions of the RFIC 3 as the controller may be disposed outside the RFIC 3, such as in the BBIC 4, the radio-frequency circuit 1, or the power supply circuit 5.

The BBIC 4 is a baseband signal processing circuit that performs signal processing by using an intermediate frequency band, which is lower than a radio-frequency signal transferred by the radio-frequency circuit 1. Examples of signals to be processed by the BBIC 4 are image signals for displaying images and/or audio signals for communication performed via a speaker.

The power supply circuit 5 is an example of a digital tracker and is able to supply a power supply voltage which is variable to multiple discrete voltage levels to the power amplifier circuit 10. That is, the power supply circuit 5 can supply a power supply voltage that can be varied (variable) to multiple discrete voltage levels. The power supply circuit 5 has two external output terminals 5a and 5b. The internal configuration of the power supply circuit 5 will be discussed later.

The digital tracker means a device that can supply a power supply voltage for a digital tracking mode. The digital tracking mode is a mode in which a power supply voltage dynamically variable to multiple discrete voltage levels can be supplied to a power amplifier to improve its efficiency. The digital tracker can thus supply a power supply voltage variable to multiple discrete voltage levels. In the first embodiment, the digital tracker supplies a power supply voltage for a digital envelope tracking mode (digital ET mode) and a power supply voltage for an average power tracking mode (APT mode) to the power amplifier circuit 10.

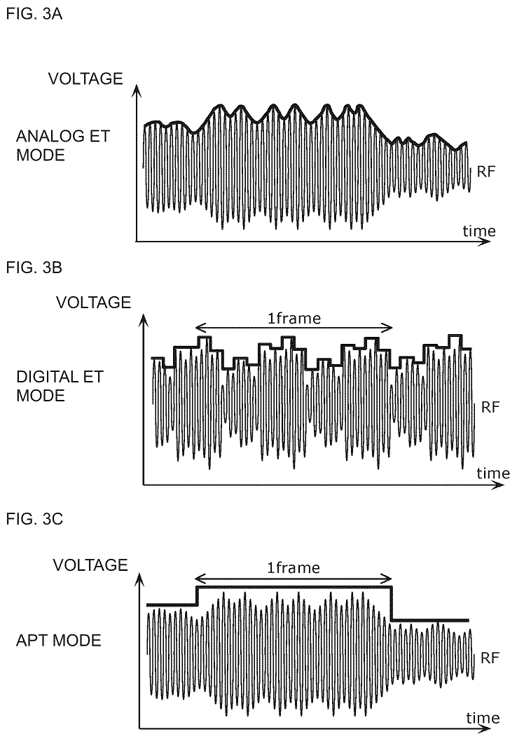

The digital ET mode is a mode in which a power supply voltage is supplied to a power amplifier so as to track the envelope of a radio-frequency signal by the use of multiple discrete voltage levels. The APT mode is a mode in which a power supply voltage is supplied to a power amplifier so as to track average power of a radio-frequency signal. Power supply voltages supplied in these modes will be explained later with reference to FIGS. 3A through 3C.

The digital tracker may be able to supply a power supply voltage for an analog tracking mode as well as a power supply voltage for a digital tracking mode. The analog tracking mode is a mode in which a power supply voltage which is dynamically variable to continuous voltage levels can be supplied.

The circuit configuration of the communication device 6 shown in FIG. 1 is an example and does not restrict the configuration of the communication device 6. In one example, the provision of the antenna 2 and/or the BBIC 4 in the communication device 6 may be omitted. In another example, the communication device 6 may include plural antennas.

### [1.1.1.2 Circuit Configuration of Radio-Frequency Circuit 1]

The circuit configuration of the radio-frequency circuit 1 will now be described below with reference to FIG. 1. The radio-frequency circuit 1 includes the power amplifier circuit 10, a switch 50, a filter 61, and the antenna connection terminal 100. The elements of the radio-frequency circuit 1 will be sequentially explained below.

The antenna connection terminal 100 is connected inside the radio-frequency circuit 1 to the switch 50 and is connected outside the radio-frequency circuit 1 to the antenna 2. A transmission signal of a predetermined band amplified by the power amplifier circuit 10 is output to the antenna 2 via the antenna connection terminal 100.

The power amplifier circuit 10 is connected to the filter 61 and can amplify a transmission signal of the predetermined band received from the RFIC 3. The internal configuration of the power amplifier circuit 10 will be discussed later.

The switch 50 is connected between the antenna connection terminal 100 and the filter 61. The switch 50 has terminals 501 through 503. The terminal 501 is connected to the antenna connection terminal 100. The terminal 502 is connected to the filter 61. The terminal 503 is connected to a filter (not shown) whose pass band is different from that of the filter 61. The terminal 503 may or may not be connected to a filter.

With this connection configuration, the switch 50 is able to connect the terminal 501 to one or both of the terminals 502 and 503 based on a control signal from the RFIC 3, for example. The switch 50 is constituted by a multiple-connection switch circuit, for example.

The filter 61 is connected between the power amplifier circuit 10 and the antenna connection terminal 100. More specifically, one end of the filter 61 is connected to the power amplifier circuit 10 and the other end thereof is connected to the antenna connection terminal 100 via the switch 50. The filter 61 has a pass band including at least part of the predetermined band. Based on frequency division duplex (FDD) being used for the predetermined band, the filter 61 has a pass band including the uplink operating band, which is part of the predetermined band. For example, based on time division duplex (TDD) being used for the predetermined band, the filter 61 has a pass band including the entirety of the predetermined band. With this configuration, the filter 61 can allow, among transmission signals amplified by the power amplifier circuit 10, a transmission signal of the predetermined band to pass therethrough.

The filter 61 may be constituted by any one of a SAW (Surface Acoustic Wave) filter, a BAW (Bulk Acoustic Wave) filter, an LC resonance filter, and a dielectric filter. The filter 61 is not limited to the above-described types of filters.

The predetermined band is a frequency band to be used for a communication system constructed using a radio access technology (RAT). The predetermined band is predefined by a standardizing body (such as 3GPP (registered trademark) (3rd Generation Partnership Project) and IEEE (Institute of Electrical and Electronics Engineers)). Examples of the communication system are a 5GNR system, an LTE system, and a WLAN (Wireless Local Area Network) system.

The radio-frequency circuit 1 shown in FIG. 1 is an example and does not restrict the configuration of the radio-frequency circuit 1. In one example, the provision of the switch 50 in the radio-frequency circuit 1 may be omitted. In another example, the radio-frequency circuit 1 may include a receive path. In another example, the radio-frequency circuit 1 may include three or more filters. In this case, the switch 50 may include four or more terminals.

### [1.1.1.3 Circuit Configuration of Power Amplifier Circuit 10]

The circuit configuration of the power amplifier circuit 10 will now be described below with reference to FIG. 1. The power amplifier circuit 10 includes power amplifiers 11 through 13, a transformer 21, a phase shifter (PS) 22, a transmission line 31, an external input terminal 111, an external output terminal 101, and power supply terminals 131 and 132. The elements of the power amplifier circuit 10 will be sequentially explained below.

The external input terminal 111 is a terminal for receiving a transmission signal of the predetermined band from the outside of the power amplifier circuit 10. The external input terminal 111 is connected outside the power amplifier circuit 10 to the RFIC 3 and is connected inside the power amplifier circuit 10 to an input terminal 11a of the power amplifier 11. With this configuration, a transmission signal of the predetermined band received from the RFIC 3 via the external input terminal 111 is supplied to the power amplifier 11.

The power supply terminal 131 is an example of a first power supply terminal, while the power supply terminal 132 is an example of a second power supply terminal. The power supply terminals 131 and 132 are terminals for receiving a power supply voltage from the power supply circuit 5.

The power supply terminal 131 is connected outside the power amplifier circuit 10 to the external output terminal 5a of the power supply circuit 5 and is connected inside the power amplifier circuit 10 to the power amplifiers 11 and 12. With this configuration, a first power supply voltage Vcc1 received from the external output terminal 5a of the power supply circuit 5 via the power supply terminal 131 is supplied to the power amplifiers 11 and 12.

The power supply terminal 132 is connected outside the power amplifier circuit 10 to the external output terminal 5b of the power supply circuit 5 and is connected inside the power amplifier circuit 10 to the power amplifier 13. With this configuration, a second power supply voltage Vcc2 received from the external output terminal 5b of the power supply circuit 5 via the power supply terminal 132 is supplied to the power amplifier 13.

The power amplifier 11 is an example of a first power amplifier and is connected between the external input terminal 111 and the power amplifiers 12 and 13. More specifically, the input terminal 11a of the power amplifier 11 is connected to the external input terminal 111, while an output terminal 11b of the power amplifier 11 is connected to the power amplifiers 12 and 13 via the phase shifter 22.

With this connection configuration, the power amplifier 11 can amplify a transmission signal of the predetermined band received via the external input terminal 111 by using the first power supply voltage Vcc1 received via the power supply terminal 131. The power amplifier 11 forms the input stage (drive stage) of a multistage amplifier circuit.

The phase shifter 22 is connected between the power amplifier 11 and the power amplifiers 12 and 13. More specifically, the input terminal of the phase shifter 22 is connected to the output terminal 11b of the power amplifier 11, while one output terminal of the phase shifter 22 is connected to an input terminal 12a of the power amplifier 12 and the other output terminal is connected to an input terminal 13a of the power amplifier 13.

With this connection configuration, the phase shifter 22 can distribute a signal amplified by the power amplifier 11 and output the resulting two signals to the power amplifiers 12 and 13. Based on distributing a signal, the phase shifter 22 can adjust the phases of the two distributed signals. For example, the phase shifter 22 shifts by −90 degrees (delays by 90 degrees) the signal to be output to the power amplifier 13 with respect to the signal to be output to the power amplifier 12. The phase adjustment to be made by the phase shifter 22 is not limited to this example. For instance, the phase shifter 22 may suitably change the phase difference of the two distributed signals based on the internal configuration of the power amplifier circuit 10.

The power amplifier 12 is an example of a second power amplifier and is connected between the power amplifier 11 and the external output terminal 101. More specifically, the input terminal 12a of the power amplifier 12 is connected to the output terminal 11b of the power amplifier 11 via the phase shifter 22, while an output terminal 12b of the power amplifier 12 is connected to the external output terminal 101 via the transformer 21.

With this connection configuration, the power amplifier 12 can amplify a transmission signal of the predetermined band amplified by the power amplifier 11 by using the first power supply voltage Vcc1 received via the power supply terminal 131. As the power amplifier 12, a Class AB amplifier is used, and the power amplifier 12 serves as a carrier amplifier of a Doherty amplifier. The power amplifier 12 is not restricted to a Class AB amplifier and a Class A amplifier, for example, may be used.

The Doherty amplifier is an amplifier which can implement high efficiency by using plural amplifiers as a carrier amplifier and a peaking amplifier. In the Doherty amplifier, the load impedance seen from the carrier amplifier changes in accordance with the output power level, thereby improving the efficiency at low power levels.

The carrier amplifier is an amplifier which is operated in a Doherty amplifier regardless of whether power of a radio-frequency signal (input) is high or low. The peaking amplifier is an amplifier which is operated in a Doherty amplifier only based on power of a radio-frequency signal (input) being high. Accordingly, based on the input power of a radio-frequency signal being low, the radio-frequency signal is amplified with the carrier amplifier. Based on the input power of a radio-frequency signal being high, the radio-frequency signal is amplified with the carrier amplifier and the peaking amplifier and the amplified signals are combined with each other. As the carrier amplifier, a Class A amplifier (including a Class AB amplifier), for example, can be used. As the peaking amplifier, a Class C amplifier, for example, can be used.

The power amplifier 13 is an example of a third power amplifier and is connected between the power amplifier 11 and the external output terminal 101. More specifically, the input terminal 13a of the power amplifier 13 is connected to the output terminal 11b of the power amplifier 11 via the phase shifter 22, while an output terminal 13b of the power amplifier 13 is connected to the external output terminal 101 via the transmission line 31 and the transformer 21.

With this connection configuration, the power amplifier 13 can amplify a transmission signal of the predetermined band amplified by the power amplifier 11 by using the second power supply voltage Vcc2 received via the power supply terminal 132. As the power amplifier 13, a Class C amplifier, for example, is used and the power amplifier 13 serves as a peaking amplifier of a Doherty amplifier. However, the power amplifier 13 is not restricted to a Class C amplifier.

In this manner, the power amplifiers 12 and 13 are connected in parallel with each other between the power amplifier 11 and the external output terminal 101. That is, the power amplifier 12 is connected to the power amplifier 11 and the external output terminal 101 without having the power amplifier 13 interposed therebetween, while the power amplifier 13 is connected to the power amplifier 11 and the external output terminal 101 without having the power amplifier 12 interposed therebetween. The power amplifiers 12 and 13 form the output stage (power stage) of the multistage amplifier circuit.

The transmission line 31 is a ¼-wavelength transmission line, for example, and can rotate the load impedance by 180 degrees on a Smith chart. The transmission line 31 may also be called a phase adjuster or a phase shifter. The length of the transmission line 31 is determined based on the predetermined band. The transmission line 31 is connected between the output terminal 13b of the power amplifier 13 and an end 211b of an input coil 211 of the transformer 21. With this connection configuration, the transmission line 31 can shift by −90 degrees (delay by 90 degrees) the phase of a transmission signal of the predetermined band amplified by the power amplifier 13. The transmission line 31 may include at least one of an inductor and a capacitor. This can reduce the length of the transmission line 31.

The transformer 21 includes an input coil 211 and an output coil 212. One end 211a of the input coil 211 is connected to the output terminal 12b of the power amplifier 12, while the other end 211b of the input coil 211 is connected to the output terminal 13b of the power amplifier 13 via the transmission line 31. One end 212a of the output coil 212 is connected to the external output terminal 101, while the other end 212b of the output coil 212 is connected to a ground. With this connection configuration, the transformer 21 can combine a transmission signal amplified by the power amplifier 12 and a transmission signal amplified by the power amplifier 13 and output the combined transmission signal to the external output terminal 101.

The external output terminal 101 is a terminal for supplying a transmission signal of the predetermined band amplified by the power amplifier circuit 10 to the outside of the power amplifier circuit 10. The external output terminal 101 is connected inside the power amplifier circuit 10 to the transformer 21 and is connected outside the power amplifier circuit 10 to the filter 61. With this configuration, a transmission signal supplied via the external output terminal 101 is transferred to the antenna connection terminal 100 via the filter 61 and the switch 50.

The circuit configuration of the power amplifier circuit 10 shown in FIG. 1 is an example and does not restrict the configuration of the power amplifier circuit 10. In one example, the provision of the transformer 21 in the power amplifier circuit 10 may be omitted. In this case, the output terminal 12b of the power amplifier 12 and the output terminal 13b of the power amplifier 13 are connected to the external output terminal 101 without having the transformer 21 interposed therebetween, and the transmission line 31 may be connected to the output terminal 12b of the power amplifier 12. In another example, the provision of the transmission line 31 and/or the phase shifter 22 in the power amplifier circuit 10 may be omitted.

### [1.1.1.4 Circuit Configuration of Power Supply Circuit 5]

The circuit configuration of the power supply circuit 5 will now be described below with reference to FIG. 2. The power supply circuit 5 includes the external output terminals 5a and 5b, an average power tracker (APT) 51, a digital envelope tracker (DET) 52, and a control circuit 53. The elements of the power supply circuit 5 will be sequentially explained below.

The external output terminals 5a and 5b are an example of different terminals of the digital tracker and are both connected to the power amplifier circuit 10. The external output terminal 5a, which is an example of a first terminal, can supply the first power supply voltage Vcc1, which is variable to multiple discrete first voltage levels. The external output terminal 5b, which is an example of a second terminal, can supply the second power supply voltage Vcc2, which is variable to multiple discrete second voltage levels.

The APT 51 is able to supply the first power supply voltage Vcc1, which is variable to the multiple discrete first voltage levels, for the APT mode. In the first embodiment, the APT 51 is connected to the external output terminal 5a and is able to supply the first power supply voltage Vcc1 to the power amplifiers 11 and 12 of the power amplifier circuit 10.

The DET 52 can supply the second power supply voltage Vcc2, which is variable to the multiple discrete second voltage levels, for the digital ET mode. The multiple discrete second voltage levels are different from the multiple discrete first voltage levels. That is, at least one of the group of the first voltage levels and the group of the second voltage levels includes a voltage level which is not included in the other one of the group of the first voltage levels and the group of the second voltage levels. In the first embodiment, the DET 52 is connected to the external output terminal 5b and is able to supply the second power supply voltage Vcc2 to the power amplifier 13 of the power amplifier circuit 10. As shown in FIG. 2, the DET 52 includes a multilevel power converter (MPC) 521 and a switch 522.

The MPC 521 can convert a reference voltage level into multiple discrete voltage levels and supply them to the switch 522. In this example, three voltage levels V1 through V3 are used as an example of the multiple discrete second voltage levels. The relationship in the magnitude of the three voltage levels satisfies V1>V2>V3>0. The number of multiple discrete voltage levels is not restricted to three. For example, the number of voltage levels may be smaller than three or larger than three. More specifically, the number of voltage levels may be 2, 4, 5, 6, 7, 8, 9, 10, or larger than 10.

The switch 522 can select one of the multiple discrete voltage levels supplied from the MPC 521 and connect a supply line of the selected voltage level to the external output terminal 5b. The switch 522 will be explained below more specifically. The switch 522 has terminals 5221 through 5224. The terminal 5221 is connected to the external output terminal 5b. The terminals 5222 through 5224 are connected to the supply lines of the voltage levels V1 through V3, respectively.

With this connection configuration, the switch 522 can select one of the three voltage levels V1 through V3 by connecting the terminal 5221 to one of the terminals 5222 through 5224. The switch 522 is constituted by an SP3T (Single-Pole Triple-Throw) switch circuit, for example.

The control circuit 53 controls the APT 51 and the DET 52. More specifically, in accordance with a control signal from the RFIC 3, for example, the control circuit 53 controls the voltage level of a power supply voltage to be supplied from each of the APT 51 and the DET 52.

The internal configuration of the DET 52 shown in FIG. 2 is an example and does not restrict the internal configuration of the DET 52. For example, the DET 52 may generate one variable voltage level. In this case, the DET 52 can generate a voltage level indicated by a control signal as appropriate.

### [1.1.2 Explanation of Digital Tracking Mode]

The digital tracking mode will be explained below. As examples of the digital tracking mode, the digital ET mode and the APT mode will be explained below by comparison with a known ET mode (hereinafter called the analog ET mode).

### [1.1.2.1 Analog ET Mode (Comparison Example)]

To explain the digital tracking mode, as an example of the analog tracking mode, which is not the digital tracking mode, the analog ET mode will be described below with reference to FIG. 3A.

FIG. 3A is a graph illustrating an example of the transition of a power supply voltage in the analog ET mode. In FIG. 3A, the horizontal axis indicates the time, and the vertical axis indicates the voltage. The thick solid line represents the power supply voltage, while the thin solid line (waveform) represents a modulated signal.

In the analog ET mode, a continuously variable power supply voltage which tracks the envelope of a modulated signal is supplied. A power supply voltage signal has, not a digital waveform, but an analog waveform.

In the analog ET mode, it may be desirable to change a power supply voltage continuously and is thus difficult to change the power supply voltage at high speed. Based on the envelope of a modulated signal fluctuating sharply, the power supply voltage may fail to track the envelope.

### [1.1.2.2 Digital ET Mode]

As an example of the digital tracking mode, the digital ET mode will now be explained below with reference to FIG. 3B.

FIG. 3B is a graph illustrating an example of the transition of a power supply voltage in the digital ET mode. In FIG. 3B, the horizontal axis indicates the time, and the vertical axis indicates the voltage. The thick solid line represents the power supply voltage, while the thin solid line (waveform) represents a modulated signal.

In the digital ET mode, a power supply voltage which is variable to multiple discrete voltage levels within one frame is supplied. A power supply voltage signal has a digital waveform and forms a rectangular wave.

A frame is a unit which forms a radio-frequency signal (modulated signal). For example, 5GNR (5th Generation New Radio) and LTE (Long Term Evolution) define that a frame includes ten subframes, each subframe includes plural slots, and each slot is constituted by plural symbols. The subframe length is 1 ms, and the frame length is 10 ms.

Specifically, in the digital ET mode, a voltage level is selected from among multiple discrete voltage levels based on an envelope signal. The voltage level is selected so as to track the envelope of a carrier wave modulated based on transmission information. More specifically, a range of envelope values associated with each of the multiple discrete voltage levels is checked and the voltage level corresponding to the envelope value of each symbol is selected. A control signal indicating the voltage level selected in this manner is output from the RFIC 3, for example, to the power supply circuit 5.

The envelope signal is a signal indicating the envelope values of a modulated signal. The envelope value is represented by a square root of (I 2+Q 2), for example. (I, Q) is a constellation point. The constellation point is a point of a digital modulated signal on a constellation diagram. (I, Q) is determined by the BBIC 4 based on transmission information, for example.

In this manner, in the digital ET mode, a voltage level selected from among multiple discrete voltage levels is supplied, so that the voltage level can be changed at high speed. Hence, despite the envelope of a modulated signal fluctuating sharply, a power supply voltage can track the envelope.

### [1.1.2.3 APT Mode]

As an example of the digital tracking mode, the APT mode will now be explained below with reference to FIG. 3C.

FIG. 3C is a graph illustrating an example of the transition of a power supply voltage in the APT mode. In FIG. 3C, the horizontal axis indicates the time, and the vertical axis indicates the voltage. The thick solid line represents the power supply voltage, while the thin solid line (waveform) represents a modulated signal.

In the APT mode, a power supply voltage which is variable to multiple discrete voltage levels in units of frames is supplied. A power supply voltage signal has a digital waveform and forms a rectangular wave.

More specifically, in the APT mode, the level of a power supply voltage is determined, not based on an envelope signal, but based on average output power. In the APT mode, the voltage level may be varied in a unit smaller than a frame (subframe, for example).

### [1.1.3 Operation of Communication Device 6]

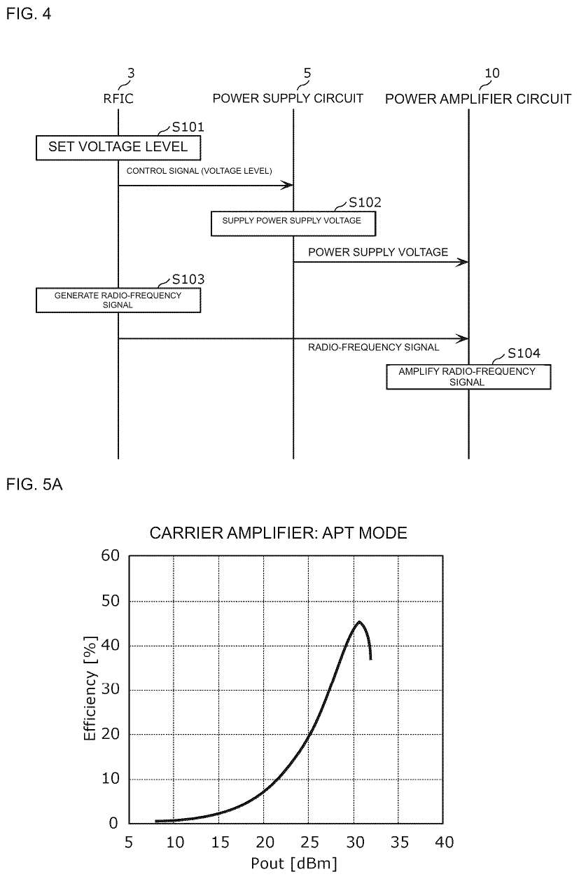

The operation of the communication device 6 according to the first embodiment will now be described below with reference to FIG. 4. FIG. 4 is a sequence diagram illustrating the operation of the communication device 6 according to the first embodiment.

The RFIC 3 first sets the level of a power supply voltage to be supplied from the power supply circuit 5 (S101). Specifically, the RFIC 3 sets the voltage level for the digital ET mode and the voltage level for the APT mode.

More specifically, based on an envelope signal, the RFIC 3 selects the voltage level for the digital ET mode from among multiple discrete voltage levels. This will be explained more specifically. The RFIC 3 obtains the envelope value of each symbol, for example. The RFIC 3 then refers to a range of envelope values associated with each of the multiple discrete voltage levels and selects the voltage level corresponding to the obtained envelope value. A control signal indicating the voltage level selected in this manner is output to the power supply circuit 5 as a control signal for the digital ET mode.

The RFIC 3 also sets the voltage level for the APT mode based on average power. A control signal indicating the set voltage level is output to the power supply circuit 5 as a control signal for the APT mode.

The power supply circuit 5 then receives the control signal from the RFIC 3 and supplies a power supply voltage to the power amplifier circuit 10 (S102). More specifically, the control circuit 53 of the power supply circuit 5 controls the APT 51 and the DET 52 in accordance with the control signal from the RFIC 3 so as to supply the power supply voltage at the set voltage level to the power amplifier circuit 10. In one example, the control circuit 53 controls the APT 51 based on the control signal for the APT mode. This enables the APT 51 to generate the first power supply voltage Vcc1 of the voltage level indicated by the control signal for the APT mode and to output the generated first power supply voltage Vcc1 to the power amplifier circuit 10. In another example, the control circuit 53 controls the switch 522 of the DET 52 based on the control signal for the digital ET mode. This enables the DET 52 to select one of the voltage levels V1 through V3 and to output the second power supply voltage Vcc2 to the power amplifier circuit 10. As a result, the APT mode is applied to the power amplifiers 11 and 12, while the digital ET mode is applied to the power amplifier 13.

Then, the RFIC 3 generates a radio-frequency signal and outputs it to the power amplifier circuit 10 (S103). The power amplifier circuit 10 amplifies the radio-frequency signal received from the RFIC 3 by using the power supply voltage supplied from the power supply circuit 5 (S104).

### [1.1.4 Relationships of Tracking Mode to Output Power and Efficiency]

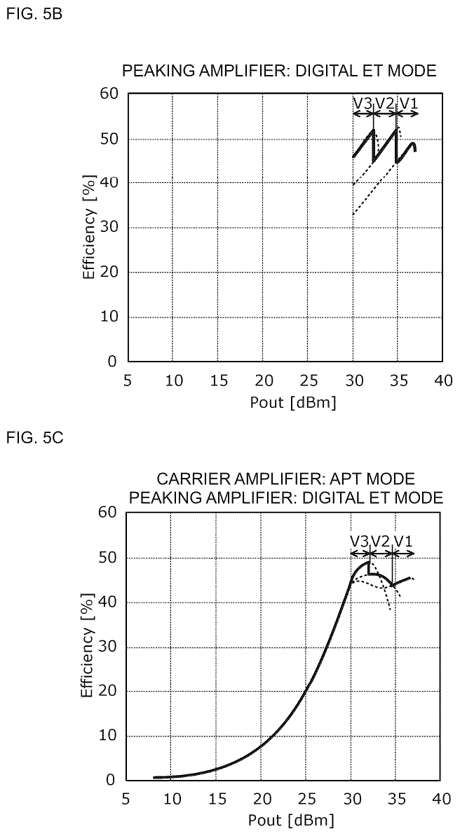

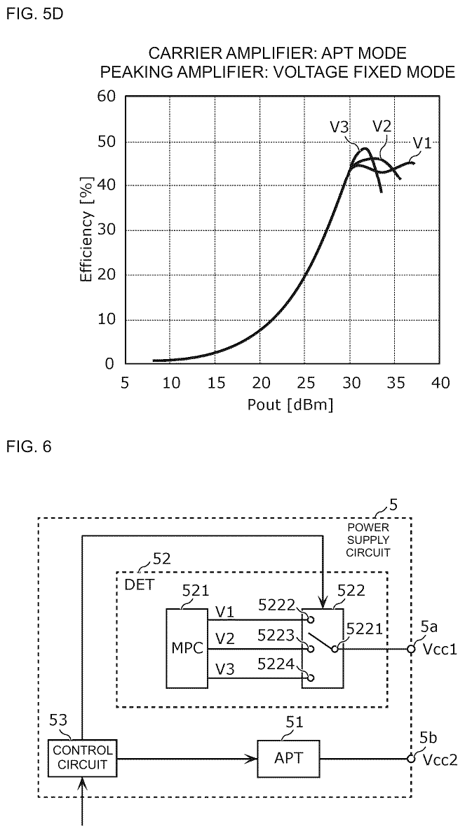

The relationships between output power and efficiency based on the above-described tracking modes being applied to power amplifiers will now be explained below with reference to FIGS. 5A through 5D.

FIG. 5A is a graph illustrating an example of the efficiency of the carrier amplifier (power amplifier 12) to which the APT mode is applied in the first embodiment. FIG. 5B is a graph illustrating an example of the efficiency of the peaking amplifier (power amplifier 13) to which the digital ET mode is applied in the first embodiment. FIG. 5C is a graph illustrating an example of the efficiency of the carrier amplifier (power amplifier 12) to which the APT mode is applied and the peaking amplifier (power amplifier 13) to which the digital ET mode is applied in the first embodiment. FIG. 5D is a graph illustrating an example of the efficiency of a carrier amplifier to which the APT mode is applied and a peaking amplifier to which a voltage fixed mode is applied in a comparative example.

In FIGS. 5A through 5D, the horizontal axis indicates output power, and the vertical axis indicates efficiency. V1 through V3 represent the above-described voltage levels of the power supply voltage. The broken line indicates the efficiency based on the voltage level being fixed.

The carrier amplifier to which the APT mode is applied will be explained below. As illustrated in FIG. 5A, based on the output power being up to about 30 dBm, the efficiency is enhanced as the output power is increased, while, based on the output power being about 30 dBm or higher, the efficiency declines as the output power is increased. To compensate for a decline in the efficiency, the peaking amplifier, which is operated based on output power being 30 dBm or higher, is used.

Based on the output power being in a region where the peaking amplifier is operated, a power supply voltage variable to the voltage levels V1 through V3 is supplied to the peaking amplifier to which the digital ET mode is applied. As a result, the efficiency of the peaking amplifier is increased and decreased in a region where the output power is 30 dBm or higher, as shown in FIG. 5B.

In the first embodiment, the carrier amplifier to which the APT mode is applied and the peaking amplifier to which the digital ET mode is applied are used. As a result, the carrier amplifier and the peaking amplifier can implement the efficiency shown in FIG. 5C.

Based on the digital ET mode being applied to the peaking amplifier (FIG. 5C), higher efficiency can be achieved in a region of the output power of 30 to 35 dBm than based on the voltage fixed mode (fixed to V1) being applied to the peaking amplifier (V1 in FIG. 5D), and higher output power can be achieved than based on the voltage fixed mode (fixed to V2/V3) being applied to the peaking amplifier (V2/V3 in FIG. 5D). In this manner, in the first embodiment, with the application of the digital ET mode to the peaking amplifier, high output power can be achieved with high efficiency.

The output power and the efficiency of the power amplifiers in the first embodiment may or may not match those of the graphs in FIGS. 5A through 5C. For example, the peaking amplifier may be operated in a region where the output power is lower than 30 dBm.

### [1.1.5 Other Considerations]

As described above, a power amplifier circuit 10 according to the first embodiment includes an external input terminal 111, an external output terminal 101, a power amplifier 11 connected to the external input terminal 111, power amplifiers 12 and 13, a power supply terminal 131 connected to the power amplifier 12, and a power supply terminal 132 connected to the power amplifier 13. The power amplifiers 12 and 13 are connected in parallel with each other between the power amplifier 11 and the external output terminal 101. A first power supply voltage which is variable to multiple discrete first voltage levels is supplied to the power amplifier 12 via the power supply terminal 131. A second power supply voltage which is variable to multiple discrete second voltage levels is supplied to the power amplifier 13 via the power supply terminal 132. The multiple discrete second voltage levels are different from the multiple discrete first voltage levels.

In other words, the power amplifier circuit 10 according to the first embodiment includes the external input terminal 111, external output terminal 101, power amplifier 11 connected to the external input terminal 111, power amplifiers 12 and 13, and power supply terminals 131 and 132 respectively connected to different external output terminals 5a and 5b of a power supply circuit 5, which serves as a digital tracker. The power amplifiers 12 and 13 are connected in parallel with each other between the power amplifier 11 and the external output terminal 101. The power supply terminal 131 is connected to the power amplifier 12, while the power supply terminal 132 is connected to the power amplifier 13. The external output terminal 5a may supply a first power supply voltage which is variable to multiple discrete first voltage levels. The external output terminal 5b may supply a second power supply voltage which is variable to multiple discrete second voltage levels. The multiple discrete second voltage levels are different from the multiple discrete first voltage levels.

With this configuration, a power supply voltage variable to multiple discrete voltage levels is supplied to each of the power amplifiers 12 and 13. It thus becomes easier for the power supply voltage to follow a fast change of a signal than based on a continuously variable power supply voltage being supplied. Additionally, the multiple discrete voltage levels of the power supply voltage supplied to the power amplifier 12 are different from those of the power supply voltage supplied to the power amplifier 13. It is thus possible to regulate a decrease in efficiency, which is caused by using multiple discrete voltage levels for a power supply voltage, compared with based on the same power supply voltage being supplied to the power amplifiers 12 and 13.

Moreover, for example, in the power amplifier circuit 10 according to the first embodiment, the power amplifier 12 may be a carrier amplifier, while the power amplifier 13 may be a peaking amplifier.

With this configuration, a power supply voltage variable to multiple discrete voltage levels suitable for the power amplifier 12, which functions as the carrier amplifier of a Doherty amplifier, can be supplied, and a power supply voltage variable to multiple discrete voltage levels suitable for the power amplifier 13, which functions as the peaking amplifier of the Doherty amplifier, can be supplied. It is thus possible to regulate a decrease in the efficiency of the Doherty amplifier, which is caused by using multiple discrete voltage levels for a power supply voltage.

Moreover, for example, in the power amplifier circuit 10 according to the first embodiment, the APT mode may be applied to the power amplifier 12, while the digital ET mode may be applied to the power amplifier 13.

With this configuration, since the digital ET mode is applied to the peaking amplifier, the efficiency at high output power can be enhanced.

Furthermore, for example, in the power amplifier circuit 10 according to the first embodiment, the power supply terminal 131 may also be connected to the power amplifier 11.

With this configuration, the same power supply voltage as that supplied to the power amplifier 12 is supplied to the power amplifier 11. Accordingly, fewer power supply terminals are required than based on a power supply voltage different from that to the power amplifier 12 being supplied to the power amplifier 11, thereby contributing to the miniaturization of the power amplifier circuit 10.

Additionally, for example, a power amplification method according to the first embodiment is a power amplification method for amplifying power of a radio-frequency signal with the use of power amplifiers 12 and 13. The power amplifiers 12 and 13 are connected in parallel with each other between a power amplifier 11 and an external output terminal 101. The power amplifier 11 is connected to an external input terminal 111. A first power supply voltage which is variable to multiple discrete first voltage levels is supplied to the power amplifier 12. A second power supply voltage which is variable to multiple discrete second voltage levels is supplied to the power amplifier 13. The multiple discrete second voltage levels are different from the multiple discrete first voltage levels.

With this method, features similar to those obtained by the above-described power amplifier circuit 10 can be achieved.

### Modified Example of First Embodiment

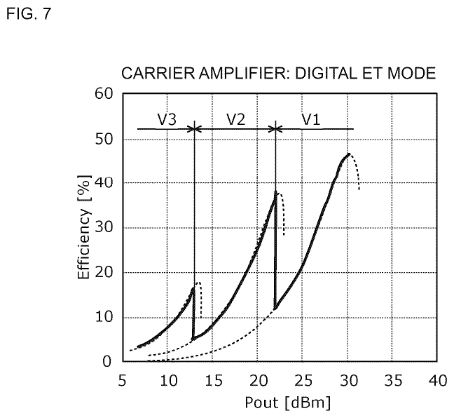

A modified example of the first embodiment will now be described below. The present modified example is different from the first embodiment mainly in that the power amplifier to which the digital ET mode is applied and the power amplifier to which the APT mode is applied are different from those in the first embodiment. In the present modified example, the digital ET mode is applied to the carrier amplifier (power amplifier 12), while the APT mode is applied to the peaking amplifier (power amplifier 13). The present modified example will be described below with reference to FIGS. 6 and 7 by mainly referring to the points different from the first embodiment.

### [1.2.1 Circuit Configuration of Power Supply Circuit 5]

The circuit configuration of a power supply circuit 5 according to the present modified example will be discussed below with reference to FIG. 6. FIG. 6 is a circuit diagram of the power supply circuit 5 according to the present modified example. In FIG. 6, a path for receiving power from an external power supply is not shown.

As illustrated in FIG. 6, the power supply circuit 5A includes an APT 51, a DET 52, and a control circuit 53. In the present modified example, the DET 52 is connected to the external output terminal 5a and is able to supply the first power supply voltage Vcc1 variable to multiple discrete first voltage levels to the power amplifiers 11 and 12 of the power amplifier circuit 10. In this example, three voltage levels V1 through V3 are an example of the multiple discrete first voltage levels. The relationship in the magnitude of the three voltage levels satisfies V1>V2>V3>0. The APT 51 is connected to the external output terminal 5b and is able to supply the second power supply voltage Vcc2 variable to multiple discrete second voltage levels to the power amplifier 13 of the power amplifier circuit 10.

### [1.2.2 Relationships of Tracking Mode to Output Power and Efficiency]

The relationships between output power and efficiency based on the above-described tracking modes being applied to the power amplifiers will now be explained below with reference to FIG. 7.

FIG. 7 is a graph illustrating an example of the efficiency of the carrier amplifier (power amplifier 12) to which the digital ET mode is applied in the present modified example. In FIG. 7, the horizontal axis indicates output power, and the vertical axis indicates efficiency.

In the carrier amplifier to which the digital ET mode is applied, as shown in FIG. 7, while the power supply voltage of the same voltage level is being supplied, the efficiency declines as the output power becomes lower. Then, based on the voltage level being switched to a lower voltage level, the efficiency rises sharply. For example, while the power supply voltage of the voltage level V1 is being supplied, the efficiency drops from 45% to 12% based on the output power being decreased from 30 dBm to 22 dBm. Then, the voltage level V1 is switched to the lower voltage level V2, and then, the efficiently sharply rises from 12% to 38%.

In the carrier amplifier to which the digital ET mode is applied, the voltage level is switched to a lower voltage level in lower output power, and then, a decrease in efficiency in low output power can be regulated.

The output power and the efficiency of the power amplifier in the present modified example may or may not match those of the graph in FIG. 7. For instance, the output power that can be implemented only by the use of the carrier amplifier may be lower than 30 dBm or higher than 30 dBm.

### [1.2.3 Other Considerations]

As described above, in the power amplifier circuit 10 according to the present modified example, the digital ET mode may be applied to the power amplifier 12, while the APT mode may be applied to the power amplifier 13.

With this configuration, since the digital ET mode is applied to the carrier amplifier, the efficiency can be improved regardless of the level of output power.

### Second Embodiment

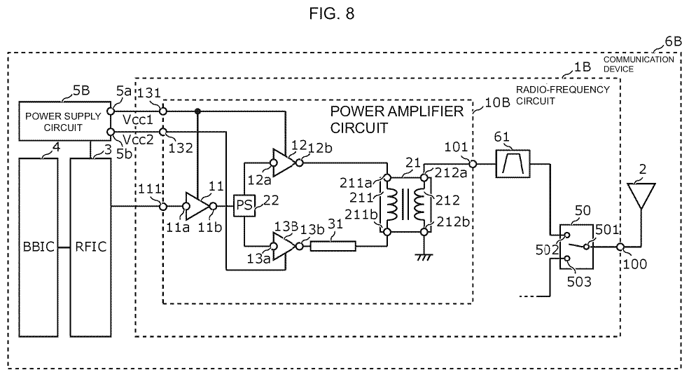

A second embodiment will now be described below. The second embodiment is different from the first embodiment mainly in that two different digital ET modes are applied to two parallel-connected amplifiers. Hereinafter, the second embodiment will be described below with reference to FIGS. 8 through 11B by mainly referring to the points different from the first embodiment.

### [2.1.1 Circuit Configuration]

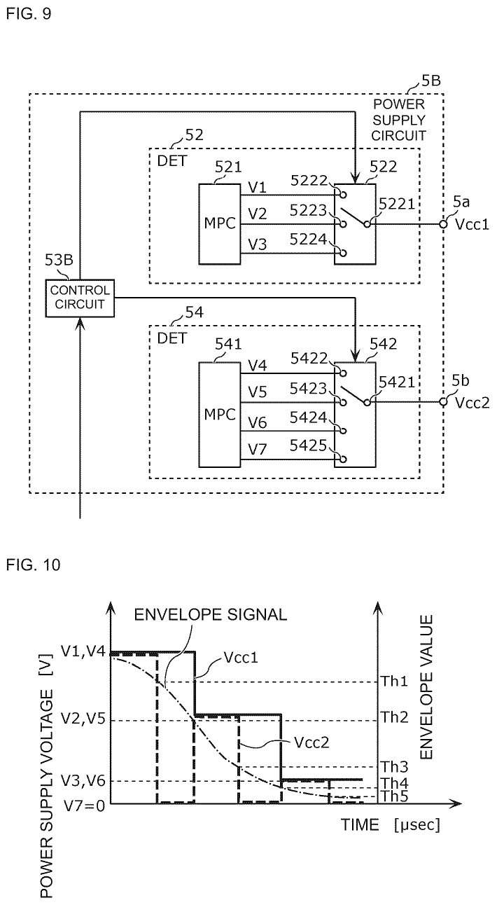

The circuit configurations of a power amplifier circuit 10B and a power supply circuit 5B according to the second embodiment will be described below with reference to FIGS. 8 and 9. FIG. 8 is a circuit diagram of the power amplifier circuit 10B, a radio-frequency circuit 1B, and a communication device 6B according to the second embodiment. FIG. 9 is a circuit diagram of the power supply circuit 5B according to the second embodiment.

The communication device 6B according to the second embodiment is similar to the communication device 6 according to the first embodiment, except that it includes the radio-frequency circuit 1B and the power supply circuit 5B instead of the radio-frequency circuit 1 and the power supply circuit 5. The radio-frequency circuit 1B according to the second embodiment is similar to the radio-frequency circuit 1 according to the first embodiment, except that it includes the power amplifier circuit 10B instead of the power amplifier circuit 10.

### [2.1.1.1 Circuit Configuration of Power Amplifier Circuit 10B]

The circuit configuration of the power amplifier circuit 10B will first be discussed below with reference to FIG. 8. The power amplifier circuit 10B includes power amplifiers 11, 12, and 13B, a transformer 21, a phase shifter 22, a transmission line 31, an external input terminal 111, an external output terminal 101, and power supply terminals 131 and 132.

The power amplifier 13B is an example of the third power amplifier and is connected between the power amplifier 11 and the external output terminal 101. More specifically, the input terminal 13a of the power amplifier 13B is connected to the output terminal 11b of the power amplifier 11 via the phase shifter 22, while the output terminal 13b of the power amplifier 13B is connected to the external output terminal 101 via the transmission line 31 and the transformer 21.

With this connection configuration, the power amplifier 13B can amplify a transmission signal of a predetermined band amplified by the power amplifier 11 by using the second power supply voltage Vcc2 received via the power supply terminal 132. The power amplifier 13B uses a Class AB amplifier but is not restricted thereto.

In this manner, the power amplifiers 12 and 13B are connected in parallel with each other between the power amplifier 11 and the external output terminal 101. That is, the power amplifier 12 is connected to the power amplifier 11 and the external output terminal 101 without having the power amplifier 13B interposed therebetween, while the power amplifier 13B is connected to the power amplifier 11 and the external output terminal 101 without having the power amplifier 12 interposed therebetween. The power amplifiers 12 and 13B connected in this manner form the output stage (power stage) of a multistage amplifier circuit.

### [2.1.1.2 Circuit Configuration of Power Supply Circuit 5B]

The circuit configuration of the power supply circuit 5B will now be described below with reference to FIG. 9. The power supply circuit 5B is an example of a digital tracker and is able to supply a power supply voltage which is variable to multiple discrete voltage levels to the power amplifier circuit 10B. The power supply circuit 5B includes two external output terminals 5a and 5b, DETs 52 and 54, and a control circuit 53B.

The DET 52 can supply a first power supply voltage Vcc1, which is variable to multiple discrete first voltage levels, for a first digital ET mode. The DET 52 is connected to the external output terminal 5a and is able to supply the first power supply voltage Vcc1 to the power amplifiers 11 and 12 of the power amplifier circuit 10B. The internal configuration of the DET 52 is similar to that of the DET 52 shown in FIG. 2 and an explanation thereof will thus be omitted.

The DET 54 can supply a second power supply voltage Vcc2, which is variable to multiple discrete second voltage levels, for a second digital ET mode. The DET 54 is connected to the external output terminal 5b and is able to supply the second power supply voltage Vcc2 to the power amplifier 13B of the power amplifier circuit 10B.

The second digital ET mode is different from the first digital ET mode. More specifically, based on a first voltage level greater than 0 being selected from among the multiple discrete first voltage levels in the first digital ET mode, in the second digital ET mode, (i) based on the envelope value of a radio-frequency signal being larger than or equal to a predetermined value, a second voltage level greater than 0 is selected from among the multiple discrete second voltage levels, and (ii) based on the envelope value of the radio-frequency signal being smaller than the predetermined value, a second voltage level equal to 0 is selected from among the multiple discrete second voltage levels.

As shown in FIG. 9, the DET 54 includes an MPC 541 and a switch 542. The MPC 541 can convert a reference voltage level into multiple discrete voltage levels and supply them to the switch 542. In this example, four voltage levels V4 through V7 are used as an example of the multiple discrete second voltage levels. The relationship in the magnitude of the four voltage levels satisfies V4>V5>V6>V7 and V7=0. The number of multiple discrete voltage levels is not restricted to four. For example, the number of voltage levels may be smaller than four or larger than four. More specifically, the number of voltage levels may be 2, 3, 5, 6, 7, 8, 9, 10, or larger than 10.

The switch 542 can select one of the multiple discrete voltage levels supplied from the MPC 541 and connect a supply line of the selected voltage level to the external output terminal 5b. The switch 542 will be explained more specifically. The switch 542 has terminals 5421 through 5425. The terminal 5421 is connected to the external output terminal 5b. The terminals 5422 through 5425 are connected to the supply lines of the voltage levels V4 through V7, respectively.

With this connection configuration, the switch 542 can select one of the four voltage levels V4 through V7 by connecting the terminal 5421 to one of the terminals 5422 through 5425. The switch 542 is constituted by an SPOT (Single-Pole Quadruple-Throw) switch circuit, for example.

The control circuit 53B controls the DETs 52 and 54. More specifically, in accordance with a control signal from the RFIC 3, for example, the control circuit 53B controls the voltage level of a power supply voltage to be supplied from each of the DETs 52 and 54.

The internal configurations of the DETs 52 and 54 shown in FIG. 9 are examples and do not restrict the internal configurations of the DETs 52 and 54. For example, the DET 52 and/or the DET 54 may generate one variable voltage level. In this case, the DET 52 and/or the DET 54 can generate a voltage level indicated by a control signal as appropriate.

### [2.1.2 Explanation of First and Second Digital ET Modes]

The first and second digital ET modes will now be explained below with reference to FIG. 10. FIG. 10 is a graph illustrating an example of the transition of a power supply voltage in each of the first and second digital ET modes in the second embodiment. In FIG. 10, the horizontal axis indicates the time, and the vertical axis indicates the power supply voltage and the envelope value. The thick solid line represents the first power supply voltage, while the thick broken line represents the second power supply voltage, and the thin long dashed dotted line represents an envelope signal.

In this example, V1>V2>V3, V4>V5>V6>V7, V1=V4, V2=V5, V3=V6, and V7=0 are satisfied.

In the first digital ET mode, based on the envelope signal, the first power supply voltage Vcc1 variable to the three voltage levels V1 through V3 is supplied to the power amplifier 12. This will be explained more specifically. Based on the envelope value being Th2 or greater, the power supply voltage of V1 is supplied. Based on the envelope value being Th4 or greater and smaller than Th2, the power supply voltage of V2 is supplied. Based on the envelope value being smaller than Th4, the power supply voltage of V3 is supplied.

In the second digital ET mode, based on the envelope signal, the second power supply voltage Vcc2 variable to the four voltage levels V4 through V7 is supplied to the power amplifier 13B. This will be explained more specifically. Based on the envelope value being Th1 or greater, the power supply voltage of V4 is supplied. Based on the envelope value being Th2 or greater and smaller than Th1, the power supply voltage of V7 is supplied. Based on the envelope value being Th3 or greater and smaller than Th2, the power supply voltage of V5 is supplied. Based on the envelope value being Th4 or greater and smaller than Th3, the power supply voltage of V7 is supplied. Based on the envelope value being Th5 or greater and smaller than Th4, the power supply voltage of V6 is supplied. Based on the envelope value being smaller than Th5, the power supply voltage of V7 is supplied.

That is, based on the voltage level V1, which is greater than 0, being selected from among the multiple discrete first voltage levels V1 through V3 in the first digital ET mode, in the second digital ET mode, (i) based on the envelope value of a radio-frequency signal being larger than or equal to the predetermined value Th1, the voltage level V4, which is greater than 0, is selected from among the multiple discrete second voltage levels V4 through V7, and (ii) based on the envelope value of the radio-frequency signal being smaller than the predetermined value Th1, the voltage level V7, which is equal to 0, is selected from among the multiple discrete second voltage levels V4 through V7. In the second digital ET mode, based on the voltage level V2, which is greater than 0, being selected from among the multiple discrete first voltage levels V1 through V3 in the first digital ET mode, (iii) based on the envelope value of the radio-frequency signal being larger than or equal to the predetermined value Th3, the voltage level V5, which is greater than 0, is selected from among the multiple discrete second voltage levels V4 through V7, and (iv) based on the envelope value of the radio-frequency signal being smaller than the predetermined value Th3, the voltage level V7, which is equal to 0, is selected from among the multiple discrete second voltage levels V4 through V7. In the second digital ET mode, based on the voltage level V3, which is greater than 0, being selected from among the multiple discrete first voltage levels V1 through V3 in the first digital ET mode, (v) based on the envelope value of the radio-frequency signal being larger than or equal to the predetermined value Th5, the voltage level V6, which is greater than 0, is selected from among the multiple discrete second voltage levels V4 through V7, and (vi) based on the envelope value of the radio-frequency signal being smaller than the predetermined value Th5, the voltage level V7, which is equal to 0, is selected from among the multiple discrete second voltage levels V4 through V7.

In this manner, while the power supply voltage of the same voltage level as that to the peaking amplifier 13B is being supplied to the power amplifier 12, the voltage level of the power supply voltage supplied to the power amplifier 13B is switched to V7, which is equal to 0. Then, based on output power being low, the operation of the power amplifier 13B can be stopped, as in a peaking amplifier.

### [2.1.3 Relationships of Tracking Mode to Output Power and Efficiency]

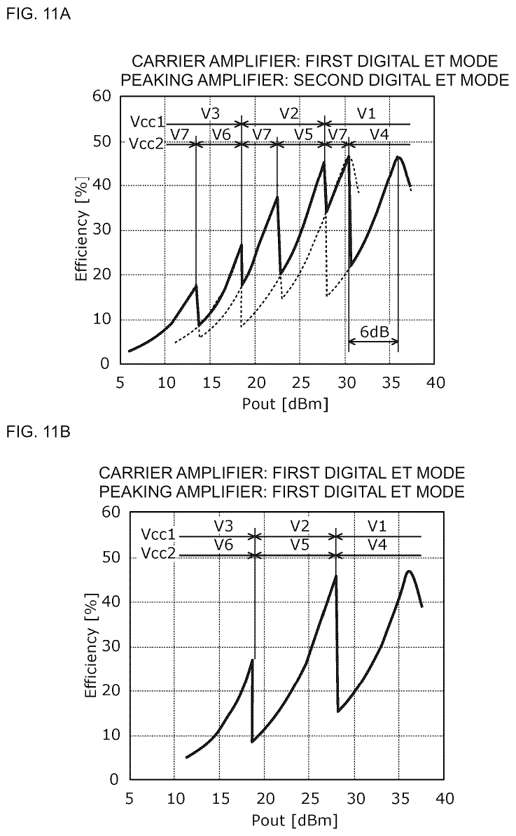

The relationships between output power and efficiency based on the above-described first and second digital ET modes being respectively applied to the power amplifiers 12 and 13B will now be explained below with reference to FIGS. 11A and 11B.

FIG. 11A is a graph illustrating an example of the efficiency of the carrier amplifier (power amplifier 12) to which the first digital ET mode is applied and the peaking amplifier (power amplifier 13B) to which the second digital ET mode is applied in the second embodiment. FIG. 11B is a graph illustrating an example of the efficiency of a carrier amplifier and a peaking amplifier to which the first digital ET mode is applied in a comparative example.

In FIGS. 11A and 11B, the horizontal axis indicates output power, and the vertical axis indicates efficiency. V1 through V7 represent the above-described voltage levels of the power supply voltage.

In the second embodiment (FIG. 11A), the first digital ET mode is applied to the carrier amplifier (power amplifier 12) and the second digital ET mode is applied to the peaking amplifier (power amplifier 13B). The voltage level of the power supply voltage supplied to each of the carrier amplifier and the peaking amplifier thus changes, and the efficiency increases and decreases in accordance with this change. For example, while the power supply voltage of V1 is being supplied to the carrier amplifier and the power supply voltage of V4 is being supplied to the peaking amplifier, based on the output power falling from 36 dBm to 30 dBm, the efficiency also decreases from 45% to 22%. Then, the voltage level of the power supply voltage supplied to the carrier amplifier is switched from V4 to V7 (=0), and then, the operation of the carrier amplifier is stopped and the efficiently rises from 22% to 45%. Then, while the power supply voltage of V1 is being supplied to the carrier amplifier and the power supply voltage of V7 is being supplied to the peaking amplifier, when the output power falls from 30 dBm to 26 dBm, the efficiency also decreases from 45% to 35%. Then, the voltage level of the power supply voltage supplied to the carrier amplifier is switched from V1 to V2 and that to the peaking amplifier is switched from to V7 to V5, and then, the efficiently rises from 35% to 45%.

In contrast, in the comparative example (FIG. 11B), the first digital ET mode is applied to both of the carrier amplifier and the peaking amplifier. The efficiency thus increases and decreases in accordance with the switching of the voltage level. For example, while the power supply voltage of V1 is being supplied to the carrier amplifier and the power supply voltage of V4 is being supplied to the peaking amplifier, when the output power falls from 36 dBm to 28 dBm, the efficiency also decreases from 45% to 16%. Then, the voltage level of the power supply voltage supplied to the carrier amplifier is switched from V1 to V2 and that to the peaking amplifier is switched from to V4 to V5, and then, the efficiently rises from 16% to 45%.

In this manner, in the second embodiment, in a range of output power while the power supply voltage of V7 is being supplied to the peaking amplifier, higher efficiency can be achieved than in the comparative example. That is, in the second embodiment, as a result of switching the voltage level of the power supply voltage supplied to the peaking amplifier to V7, which is equal to 0, it is possible to regulate a decrease in efficiency, which would be caused by supplying the power supply voltage of the same level as that to the peaking amplifier to the carrier amplifier, despite output power being decreased.

### [2.1.4 Other Considerations]

As described above, in a power amplifier circuit 10B according to the second embodiment, the first digital ET mode may be applied to the power amplifier 12, and the second digital ET mode, which is different from the first digital ET mode, may be applied to the power amplifier 13B.

In this configuration, two different digital ET modes are applied to the power amplifiers 12 and 13B. It is thus possible to regulate a decrease in efficiency, which is caused by using multiple discrete voltage levels for a power supply voltage, compared with based on the same power supply voltage being supplied to the power amplifiers 12 and 13B.

Additionally, for example, in the power amplifier circuit 10B according to the second embodiment, based on a first voltage level greater than 0 being selected from among the multiple discrete first voltage levels in the first digital ET mode, in the second digital ET mode, (i) based on the envelope value of a radio-frequency signal being larger than or equal to a predetermined value, a second voltage level greater than 0 may be selected from among the multiple discrete second voltage levels, and (ii) based on the envelope value of the radio-frequency signal being smaller than the predetermined value, a second voltage level equal to 0 may be selected from among the multiple discrete second voltage levels.

With this configuration, as a result of selecting the second voltage level which is equal to 0 as the voltage level of the power supply voltage to be supplied to the peaking amplifier, it is possible to regulate a decrease in efficiency, which would be caused by supplying the power supply voltage of the same level as that to the peaking amplifier to the carrier amplifier, even based on output power being decreased.

### (First Modified Example of Second Embodiment)

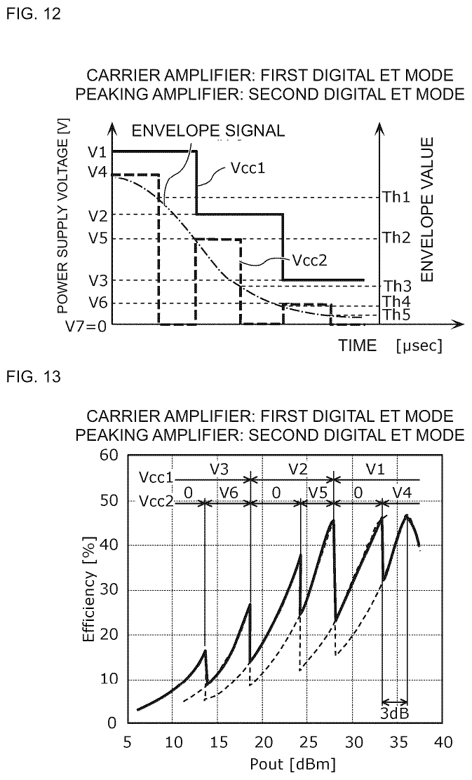

A first modified example of the second embodiment will now be described below. The first modified example is different from the second embodiment mainly in the voltage level of a power supply voltage supplied in each of the first and second digital ET modes. Hereinafter, the first modified example will be described below with reference to FIGS. 12 and 13 by mainly referring to the points different from the second embodiment.

### [2.2.1 Explanation of First and Second Digital ET Modes]

The first and second digital ET modes in the first modified example will now be explained below with reference to FIG. 12. FIG. 12 is a graph illustrating an example of the transition of a power supply voltage in each of the first and second digital ET modes in the first modified example. In FIG. 12, the horizontal axis indicates the time, and the vertical axis indicates the power supply voltage and the envelope value. The thick solid line represents the first power supply voltage, while the thick broken line represents the second power supply voltage, and the thin long dashed dotted line represents an envelope signal.

In this example, V1>V4>V2>V5>V3>V6>V7 and V7=0 are satisfied. That is, V1 in the first digital ET mode is greater than V4 in the second digital ET mode. Likewise, V2 is greater than V5, and V3 is greater than V6. In other words, in the first modified example, each of the multiple discrete first voltage levels for the first digital ET mode is greater than the corresponding second voltage level among the multiple discrete second voltage levels for the second digital ET mode.

### [2.2.2 Relationships of Tracking Mode to Output Power and Efficiency]

The relationships between output power and efficiency based on the above-described first and second digital ET modes being respectively applied to the power amplifiers 12 and 13B will now be explained below with reference to FIG. 13.

FIG. 13 is a graph illustrating an example of the efficiency of the carrier amplifier (power amplifier 12) to which the first digital ET mode is applied and the peaking amplifier (power amplifier 13B) to which the second digital ET mode is applied in the first modified example. In FIG. 13, the horizontal axis indicates output power, and the vertical axis indicates efficiency. V1 through V7 represent the above-described voltage levels of the power supply voltage.

In the first modified example (FIG. 13), the voltage level V1 of the power supply voltage supplied to the carrier amplifier (power amplifier 12) is greater than the voltage level V4 of the power supply voltage supplied to the peaking amplifier (power amplifier 13B). This can decrease variations in each of the output power and the efficiency, which are generated in accordance with whether the peaking amplifier is operated, thereby making a difference in peak-efficiency output power (back-off) smaller. For example, the back-off is 3 dB in FIG. 13, which is smaller than 6 dB in FIG. 11A.

In this manner, in the first modified example, in the first digital ET mode, the voltage level greater than that in the second digital ET mode is used so as to reduce the back-off, which is generated in accordance with whether the peaking amplifier is operated. It is thus possible to regulate a decrease in efficiency, which would be caused by supplying the power supply voltage of the same level as that to the peaking amplifier to the carrier amplifier, despite output power being decreased.

### [2.2.3 Other Considerations]

As described above, in the power amplifier circuit 10B according to the second embodiment, each of the multiple discrete first voltage levels may be greater than a corresponding second voltage level among the multiple discrete second voltage levels.

With this configuration, in the first digital ET mode, a voltage level greater than that in the second digital ET mode is used. Hence, the back-off, which is generated in accordance with whether the peaking amplifier is operated, can be reduced. It is thus possible to regulate a decrease in efficiency, which would be caused by supplying the power supply voltage of the same level as that to the peaking amplifier to the carrier amplifier, despite output power being decreased.

### (Second Modified Example of Second Embodiment)

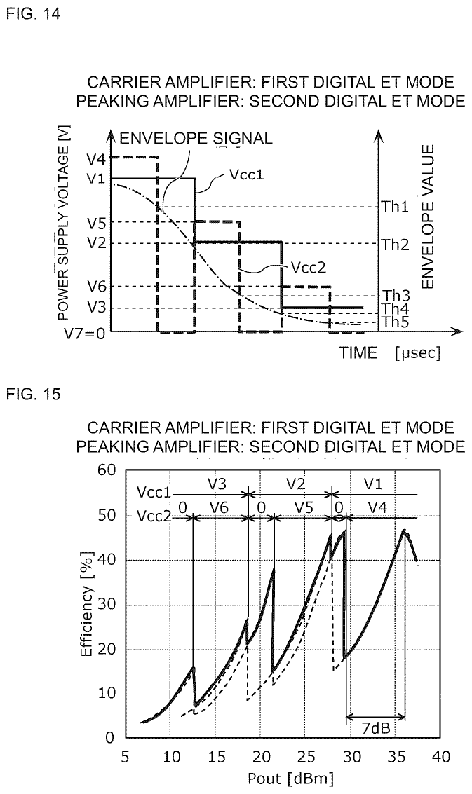

A second modified example of the second embodiment will now be described below. The second modified example is different from the second embodiment mainly in the voltage level of a power supply voltage supplied in each of the first and second digital ET modes. Hereinafter, the second modified example will be described below with reference to FIGS. 14 and 15 by mainly referring to the points different from the second embodiment.

### [2.3.1 Explanation of First and Second Digital ET Modes]

The first and second digital ET modes in the second modified example will now be explained below with reference to FIG. 14. FIG. 14 is a graph illustrating an example of the transition of a power supply voltage in each of the first and second digital ET modes in the second modified example. In FIG. 14, the horizontal axis indicates the time, and the vertical axis indicates the power supply voltage and the envelope value. The thick solid line represents the first power supply voltage, while the thick broken line represents the second power supply voltage, and the thin long dashed dotted line represents an envelope signal.

In this example, V4>V1>V5>V2>V6>V3>V7 and V7=0 are satisfied. That is, V1 in the first digital ET mode is smaller than V4 in the second digital ET mode. Likewise, V2 is smaller than V5, and V3 is smaller than V6. In other words, in the second modified example, each of the multiple discrete first voltage levels for the first digital ET mode is smaller than the corresponding second voltage level among the multiple discrete second voltage levels for the second digital ET mode.

### [2.3.2 Relationships of Tracking Mode to Output Power and Efficiency]

The relationships between output power and efficiency based on the above-described first and second digital ET modes being respectively applied to the power amplifiers 12 and 13B will now be explained below with reference to FIG. 15.

FIG. 15 is a graph illustrating an example of the efficiency of the carrier amplifier (power amplifier 12) to which the first digital ET mode is applied and the peaking amplifier (power amplifier 13B) to which the second digital ET mode is applied in the second modified example. In FIG. 15, the horizontal axis indicates output power, and the vertical axis indicates efficiency. V1 through V7 represent the above-described voltage levels of the power supply voltage.

In the second modified example (FIG. 15), the voltage level V1 of the power supply voltage supplied to the carrier amplifier (power amplifier 12) is smaller than the voltage level V4 of the power supply voltage supplied to the peaking amplifier (power amplifier 13B). This increases variations in each of the output power and the efficiency, which are generated in accordance with whether the peaking amplifier is operated, thereby making a difference in peak-efficiency output power (back-off) larger. For example, the back-off is 7 dB in FIG. 15, which is greater than 6 dB in FIG. 11A.

In this manner, in the second modified example, in the first digital ET mode, the voltage level smaller than that in the second digital ET mode is used so as to increase the back-off, which is generated in accordance with whether the peaking amplifier is operated.

### [2.3.3 Other Considerations]

As described above, in the power amplifier circuit 10B according to the second embodiment, each of the multiple discrete first voltage levels may be smaller than a corresponding second voltage level among the multiple discrete second voltage levels.

With this configuration, in the first digital ET mode, a voltage level smaller than that in the second digital ET mode is used. It is thus possible to increase the back-off, which is generated in accordance with whether the peaking amplifier is operated.

### Third Embodiment

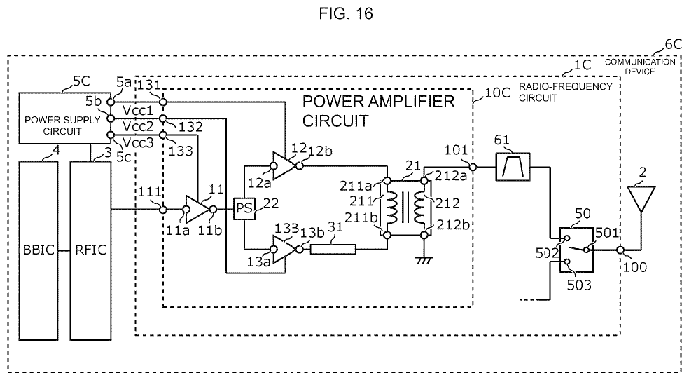

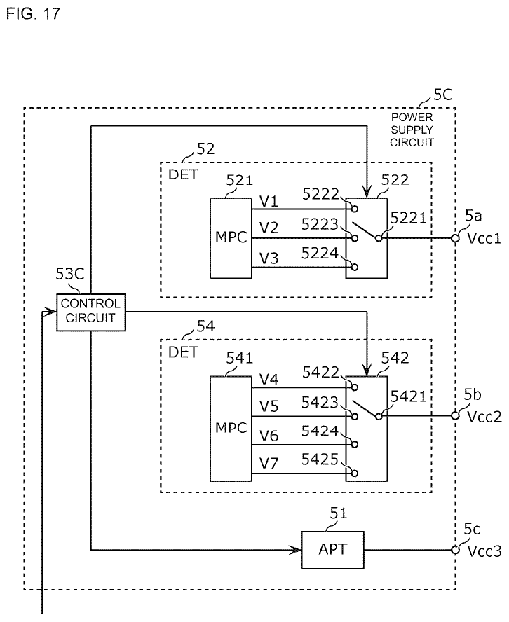

A third embodiment will now be described below. The third embodiment is different from the second embodiment mainly in that a power supply voltage different from that supplied to the power amplifier 12 is supplied to the power amplifier 11. Hereinafter, the third embodiment will be described below with reference to FIGS. 16 and 17 by mainly referring to the points different from the second embodiment.

### [3.1.1 Circuit Configuration]

The circuit configurations of a power amplifier circuit 10C and a power supply circuit 5C according to the third embodiment will be described below with reference to FIGS. 16 and 17. FIG. 16 is a circuit diagram of the power amplifier circuit 10C, a radio-frequency circuit 1C, and a communication device 6C according to the third embodiment. FIG. 17 is a circuit diagram of the power supply circuit 5C according to the third embodiment.

The communication device 6C according to the third embodiment is similar to the communication device 6B according to the second embodiment, except that it includes the radio-frequency circuit 1C and the power supply circuit 5C instead of the radio-frequency circuit 1B and the power supply circuit 5B. The radio-frequency circuit 1C according to the third embodiment is similar to the radio-frequency circuit 1B according to the second embodiment, except that it includes the power amplifier circuit 10C instead of the power amplifier circuit 10B. The power amplifier circuit 10C according to the third embodiment is similar to the power amplifier circuit 10B according to the second embodiment, except that it also includes a power supply terminal 133.

### [3.1.1.1 Circuit Configuration of Power Supply Circuit 5C]

The circuit configuration of the power supply circuit 5C will now be described below with reference to FIG. 17. The power supply circuit 5C is an example of a digital tracker and is able to supply a power supply voltage which is variable to multiple discrete voltage levels to the power amplifier circuit 10C. The power supply circuit 5C includes an APT 51, DETs 52 and 54, and a control circuit 53C.

The APT 51 supplies a third power supply voltage Vcc3 for the APT mode to the power amplifier 11 of the power amplifier circuit 10C via an external output terminal 5c.

The DET 52 supplies the first power supply voltage Vcc1 for the first digital ET mode to the power amplifier 12 of the power amplifier circuit 10C via the external output terminal 5a. The internal configuration of the DET 52 is similar to that of the DET 52 shown in FIGS. 2 and 9 and an explanation thereof will thus be omitted.

The DET 54 supplies the second power supply voltage Vcc2 for the second digital ET mode, which is different from the first digital ET mode, to the power amplifier 13B of the power amplifier circuit 10C via the external output terminal 5b. The internal configuration of the DET 54 is similar to that of the DET 54 shown in FIG. 9 and an explanation thereof will thus be omitted.

### [3.1.2 Other Considerations]

As described above, a power amplifier circuit 10C according to the third embodiment also includes a power supply terminal 133 connected to the power amplifier 11. A third power supply voltage variable to multiple discrete third voltage levels is supplied to the power amplifier 11 via the power supply terminal 133. The average power tracking mode may be applied to the power amplifier 11.

With this configuration, since the APT mode is applied to the power amplifier 11, which corresponds to the input stage, the distortion of a radio-frequency signal can be reduced compared with based on the digital ET mode being applied to the power amplifier 11.

### OTHER EMBODIMENTS

The power amplifier circuit, radio-frequency circuit, communication device, and power amplification method according to the present disclosure have been discussed above through illustration of the embodiments. However, the power amplifier circuit, radio-frequency circuit, communication device, and power amplification method according to the disclosure are not restricted to the above-described embodiments. Other embodiments implemented by combining certain elements in the above-described embodiments and modified examples obtained by making various modifications to the above-described embodiments by those skilled in the art without departing from the scope and spirit of the disclosure are also encompassed in the disclosure. Various types of equipment integrating the above-described radio-frequency circuits are also encompassed in the disclosure.

In one example, in the circuit configurations of the power amplifier circuits, radio-frequency circuits, and communication devices according to the above-described embodiments, another circuit element and another wiring may be inserted onto a path connecting circuit elements and/or onto a path connecting signal paths illustrated in the drawings. For instance, an impedance matching circuit may be inserted between the filter 61 and the power amplifier circuit 10 and/or between the filter 61 and the antenna connection terminal 100. Likewise, an impedance matching circuit may be inserted between another two circuit elements. The impedance matching circuit can be constituted by an inductor and/or a capacitor, for example.

In another example, in the first modified example of the first embodiment, the second embodiment, or the modified examples of the second embodiment, an LDO (Low Dropout) circuit may be connected between the power supply terminal 131 and the power amplifier 11. With this configuration, a first power supply voltage Vcc1 restricted by the LDO circuit is supplied to the power amplifier 11. This can efficiently lower gain deviation which is generated in the case of supplying the power supply voltage Vcc of multiple discrete voltage levels V1 through V3 to the power amplifier 11.

In each of the above-described embodiments, the power amplifier circuit includes a transformer 21. However, the power amplifier circuit is not restricted to this configuration. For instance, the provision of the transformer 21 in the power amplifier circuit may be omitted. In this case, the output terminal 12b of the power amplifier 12 and the output terminal 13b of the power amplifier 13 or 13B are connected to the external output terminal 101 without having the transformer 21 interposed therebetween. In this case, the transmission line 31 may be connected between the output terminal 12b of the power amplifier 12 and the external output terminal 101.

In the above-described embodiments, the power amplifiers 12 and 13 or 13B serve as a Doherty amplifier. However, this is only an example. For instance, the power amplifiers 12 and 13 or 13B may serve as a differential composition amplifier. In this case, the phase shifter 22 may shift the input signal to be output to the power amplifier 12 by 180 degrees with respect to the input signal to be output to the power amplifier 13 or 13B. In another example, the power amplifiers 12 and 13 or 13B may serve as an in-phase composition amplifier. In this case, the provision of the phase shifter 22 in the power amplifier circuit 10, 10B, or 10C may be omitted.

### INDUSTRIAL APPLICABILITY

The present disclosure can be widely used in communication equipment, such as mobile phones, as a power amplifier circuit or a radio-frequency circuit disposed in a multiband-support front-end section.

### REFERENCE SIGNS LIST

1, 1B, 1C radio-frequency circuit
2 antenna
3 RFIC
4 BBIC
5, 5A, 5B, 5C power supply circuit
5a, 5b, 5c, 101 external output terminal
6, 6B, 6C communication device
10, 10B, 10C power amplifier circuit
11, 12, 13, 13B power amplifier
11a, 12a, 13a input terminal
11b, 12b, 13b output terminal
21 transformer
22 phase shifter
31 transmission line
50, 522, 542 switch
51 APT
52, 54 DET
53, 53B, 53C control circuit
61 filter
100 antenna connection terminal
111 external input terminal
131, 132, 133 power supply terminal
211 input coil
211a one end of input coil
211b the other end of input coil
212 output coil
212a one end of output coil
212b the other end of output coil
501, 502, 503, 5221, 5222, 5223, 5224, 5421, 5422, 5423,
5424, 5425 terminal
521, 541 MPC

1. A power amplifier circuit comprising:
an external input terminal and an external output terminal;
a first power amplifier connected to the external input terminal;
second and third power amplifiers;
a first power supply terminal connected to the second power amplifier; and
a second power supply terminal connected to the third power amplifier, wherein
the second and third power amplifiers are connected in parallel with each other between the first power amplifier and the external output terminal,
a first power supply voltage which is variable to multiple discrete first voltage levels is supplied to the second power amplifier via the first power supply terminal, and
a second power supply voltage which is variable to multiple discrete second voltage levels is supplied to the third power amplifier via the second power supply terminal, the multiple discrete second voltage levels being different from the multiple discrete first voltage levels.

2. The power amplifier circuit according to claim 1, wherein:
the second power amplifier is a carrier amplifier; and
the third power amplifier is a peaking amplifier.

3. The power amplifier circuit according to claim 2, wherein:
an average power tracking mode is applied to the second power amplifier; and
a digital envelope tracking mode is applied to the third power amplifier.

4. The power amplifier circuit according to claim 2, wherein:
a digital envelope tracking mode is applied to the second power amplifier; and
an average power tracking mode is applied to the third power amplifier.

5. The power amplifier circuit according to claim 2, wherein:
a first digital envelope tracking mode is applied to the second power amplifier; and
a second digital envelope tracking mode is applied to the third power amplifier, the second digital envelope tracking mode being different from the first digital envelope tracking mode.

6. The power amplifier circuit according to claim 5, wherein, based on a first voltage level greater than 0 being selected from among the multiple discrete first voltage levels in the first digital envelope tracking mode, in the second digital envelope tracking mode,
(i) based on an envelope value of a radio-frequency signal being larger than or equal to a predetermined value, a second voltage level greater than 0 is selected from among the multiple discrete second voltage levels, and
(ii) based on the envelope value of the radio-frequency signal being smaller than the predetermined value, a second voltage level equal to 0 is selected from among the multiple discrete second voltage levels.

7. The power amplifier circuit according to claim 5, wherein each of the multiple discrete first voltage levels is greater than a corresponding second voltage level among the multiple discrete second voltage levels.

8. The power amplifier circuit according to claim 5, wherein each of the multiple discrete first voltage levels is smaller than a corresponding second voltage level among the multiple discrete second voltage levels.

9. The power amplifier circuit according to claim 8, wherein the first power supply terminal is also connected to the first power amplifier.

10. A power amplifier circuit comprising:
an external input terminal and an external output terminal;
a first power amplifier connected to the external input terminal;
second and third power amplifiers; and
first and second power supply terminals separately connected to different terminals of a digital tracker, wherein
the second and third power amplifiers are connected in parallel with each other between the first power amplifier and the external output terminal,
the first power supply terminal is connected to the second power amplifier, and
the second power supply terminal is connected to the third power amplifier.

11. The power amplifier circuit according to claim 10, wherein:
the second power amplifier is a carrier amplifier; and
the third power amplifier is a peaking amplifier.

12. The power amplifier circuit according to claim 11, wherein the different terminals of the digital tracker include first and second terminals, the first terminal being used for supplying a first power supply voltage which is variable to multiple discrete first voltage levels, the second terminal being used for supplying a second power supply voltage which is variable to multiple discrete second voltage levels, the multiple discrete second voltage levels being different from the multiple discrete first voltage levels.

13. The power amplifier circuit according to claim 12, wherein:
an average power tracking mode is applied to the second power amplifier; and
a digital envelope tracking mode is applied to the third power amplifier.

14. The power amplifier circuit according to claim 12, wherein:
a digital envelope tracking mode is applied to the second power amplifier; and
an average power tracking mode is applied to the third power amplifier.

15. The power amplifier circuit according to claim 12, wherein:
a first digital envelope tracking mode is applied to the second power amplifier; and
a second digital envelope tracking mode is applied to the third power amplifier, the second digital envelope tracking mode being different from the first digital envelope tracking mode.

16. The power amplifier circuit according to claim 15, wherein, based on a first voltage level greater than 0 being selected from among the multiple discrete first voltage levels in the first digital envelope tracking mode, in the second digital envelope tracking mode,
(i) based on an envelope value of a radio-frequency signal being larger than or equal to a predetermined value, a second voltage level greater than 0 is selected from among the multiple discrete second voltage levels, and
(ii) based on the envelope value of the radio-frequency signal being smaller than the predetermined value, a second voltage level equal to 0 is selected from among the multiple discrete second voltage levels.

17. The power amplifier circuit according to claim 15, wherein each of the multiple discrete first voltage levels is greater than a corresponding second voltage level among the multiple discrete second voltage levels.

18. The power amplifier circuit according to claim 15, wherein each of the multiple discrete first voltage levels is smaller than a corresponding second voltage level among the multiple discrete second voltage levels.

19. The power amplifier circuit according to claim 18, wherein the first power supply terminal is also connected to the first power amplifier.

20. A power amplification method for amplifying power of a radio-frequency signal by using second and third power amplifiers, the second and third power amplifiers being connected in parallel with each other between a first power amplifier and an external output terminal, the first power amplifier being connected to an external input terminal, comprising:
supplying a first power supply voltage which is variable to multiple discrete first voltage levels to the second power amplifier; and
supplying a second power supply voltage which is variable to multiple discrete second voltage levels to the third power amplifier, the multiple discrete second voltage levels being different from the multiple discrete first voltage levels.
